(19) United States
(12) Patent Application Publication
(10) Pub. No.: US 2007/0160774 A1
(43) Pub. Date: Jul. 12, 2007

(54) Method for producing silicon nitride films and silicon oxynitride films by chemical vapor deposition

(76) Inventors: Eri Tsukada, Ibaraki (JP); Christian Dussarrat, Ibaraki (JP); Jean-Marc Girard, Paris (FR)

Correspondence Address: AIR LIQUIDE;Intellectual Property, 2700 POST OAK BOULEVARD, SUITE 1800, HOUSTON, TX, 77056, US

(21) Appl. No.: 10/587,427

(22) PCT Filed: Jan. 19, 2005
(86) PCT No.: PCT/IB05/00170

§ 371 Date: Jul. 26, 2006

(30) Foreign Application Priority Data
Feb. 2, 2004 (JP) 2004-025479

(51) Int. Cl. H05H 1/24; H01L 21/31

(52) U.S. Cl. 427/579; 438/791; 438/792

(57) ABSTRACT

To provide a CVD-based method for the relatively low temperature production of silicon nitride films and silicon oxynitride films that exhibit excellent film properties wherein said method is not accompanied by the production of ammonium chloride. Gaseous aminosilane such as tris(isopropylamino)silane and a gaseous hydrazine compound such as dimethylhydrazine are fed into a chemical vapor deposition reaction chamber that holds at least one substrate and silicon nitride film is formed on the substrate by reacting the two gases in said chemical vapor deposition reaction chamber.

This invention relates to a method for producing silicon nitride films and silicon oxynitride films. More particularly, this invention relates to a method for producing silicon nitride films and silicon oxynitride films by chemical vapor deposition (CVD).

Silicon nitride films have excellent barrier properties and exhibit an excellent oxidation resistance and for these reasons are used in the fabrication of microelectronic devices as, for example, an etch stop layer, barrier layer, gate dielectric layer, ONO stack, and so forth.

Plasma-enhanced CVD (PECVD) and low-pressure CVD (LPCVD) are the main methods in use at the present time to form silicon nitride films.

PECVD is typically carried out by introducing a silicon source (typically silane) and a nitrogen source (typically ammonia and most recently nitrogen) between a pair of parallel plate electrodes and generating a plasma from the silicon source and nitrogen source at low temperature (about 300° C.) and low pressure (0.1 torr to 5 torr) by applying high-frequency energy between the electrodes. A silicon nitride film is produced by reaction of the active nitrogen species in the plasma with the active silicon species. The silicon nitride films produced by PECVD in this manner typically do not have a stoichiometric composition and are also hydrogen rich. As a consequence, these silicon nitride films exhibit a low film density and an inadequate thermal stability; they also exhibit poor step coverage.

LPCVD uses low pressures (0.1 to 5 torr) and high temperatures (800-900° C.). The silicon nitride films afforded by LPCVD have better properties than those of the silicon nitride films produced by PECVD. At the present time, silicon nitride is typically produced by LPCVD by the reaction of dichlorosilane and ammonia gas. However, ammonium chloride is a by-product of the reaction of dichlorosilane and ammonia gas in LPCVD: this ammonium chloride deposits in and clogs the exhaust lines of the reaction device and also deposits on the wafer. LPCVD also has a high thermal budget.

The production of silicon nitride by the reaction of hexachlorodisilane and ammonia has recently been introduced in order to reduce the thermal budget (Nonpatent Reference 1). However, due to the large number of chlorine atoms in each molecule of hexachlorodisilane, the use of hexachlorodisilane in fact worsens the problem of ammonium chloride deposition. Moreover, the use of hexachlorodisilane results in the production of silicon-containing particles, which causes a substantial shortening of the life of the pumping system.

Another method that has been introduced in order to reduce the thermal budget involves the reaction of ammonia with an organosilicon source (silazane, aminosilane) (Nonpatent Reference 2). This method, however, still uses a high reaction temperature and has a relatively high reaction activation energy.

[Nonpatent Reference 1]

M. Tanaka et al., Journal of the Electrochemical Society, Volume 147, p. 2284 (2000).
   [Nonpatent Reference 2]
R. K. Laxman et al., Proceedings of the VMIC Conference, p. 568 (1998).

The object of this invention, therefore, is to provide a CVD-based method for the relatively low temperature production of silicon nitride films and silicon oxynitride films that exhibit excellent film properties wherein said method is not accompanied by the production of ammonium chloride.

According to a first aspect of the present invention, there is provided a method for producing silicon nitride film by chemical vapor deposition, said method being characterized by feeding gaseous aminosilane with formula (I)
(H)ₙ—Si—(N(R)₂)₄₋ₙ (1)
(each R is independently selected from the hydrogen atom, C₁₋₄ alkyl, and the trimethylsilyl group and n is an integer with a value of 0-3, wherein the groups R are not all simultaneously a hydrogen atom)

and gaseous hydrazine compound with formula (II)
N₂(H)₄₋ₓ(R¹)ₓ (II)
(each R¹ is independently selected from methyl, ethyl, and phenyl and x is an integer with a value of 0-4)

into a chemical vapor deposition reaction chamber that holds at least one substrate, and

forming silicon nitride film on said at least one substrate by reacting the two gases in the chemical vapor deposition reaction chamber.

According to a second aspect of the present invention, there is provided a method for producing silicon oxynitride film by chemical vapor deposition, said method being characterized by

feeding gaseous aminosilane with formula (I)
(H)ₙ—Si—(N(R)₂)₄₋ₙ (I)
(each R is independently selected from the hydrogen atom, C₁₋₄ alkyl, and the trimethylsilyl group and n is an integer with a value of 0-3, wherein the groups R are not all simultaneously a hydrogen atom),

gaseous hydrazine compound with formula (II)
N₂(H)₄₋ₓ(R¹)ₓ (II)
(each R¹ is independently selected from methyl, ethyl, and phenyl and x is an integer with a value of 0-4), and oxygenated gas

into a chemical vapor deposition reaction chamber that holds at least one substrate, and

forming silicon oxynitride film on said at least one substrate by reacting these gases in the chemical vapor deposition reaction chamber.

This invention provides a CVD-based method for the relatively low temperature production of silicon nitride films and silicon oxynitride films that exhibit excellent film properties wherein said method is not accompanied by the production of ammonium chloride.

This invention is described in additional detail hereinbelow.

This invention relates to a method for forming a silicon nitride film or silicon oxynitride film (in some instances collectively referred to hereinbelow as silicon (oxy)nitride film) on a substrate by CVD. The inventive method encompasses the use of gaseous aminosilane with formula (I) as precursor for the silicon (oxy)nitride film
(H)ₙ—Si—(N(R)₂)₄₋ₙ (I)
and the reaction therewith of gaseous hydrazine compound with formula (II).
N₂(H )₄₋ₓ(R¹ )ₓ (II)
Each R in formula (I) is independently selected from the hydrogen atom, C₁₋₄ alkyl, and the trimethylsilyl group (—Si(CH₃)₃), while the subscript n is an integer with a value of 0 to 3. However, the groups R may not all simultaneously be a hydrogen atom. Each R¹ in formula (II) is independently selected from methyl, ethyl, and phenyl, while the subscript x is an integer with a value of 0 to 4.

Specific examples of the aminosilane (I) are bis(tert-butylamino)silane (BTBAS), tris(isopropylamino)silane (TIPAS), and tetrakis(ethylamino)silane (TEAS). The hydrazine compound (II) can be specifically exemplified by dimethylhydrazines such as 1,1-dimethylhydrazine (UDMH).

The production of silicon nitride films will be described first. In this case, the gaseous aminosilane and gaseous hydrazine compound, along with inert diluent gas as necessary or desired, are fed into a chemical vapor deposition reaction chamber (referred to below as the CVD reaction chamber) that holds at least one semiconductor substrate and the gaseous aminosilane and gaseous hydrazine compound are therein reacted to produce a silicon nitride film on the substrate.

The interior of the CVD reaction chamber can be maintained under a pressure from 0.1 torr to 1000 torr during this reaction between the gaseous aminosilane and gaseous hydrazine compound. This reaction (formation of silicon nitride film) can generally be run at the relatively low temperatures of 300° C. to 650° C. An appropriate gaseous aminosilane : gaseous hydrazine compound molar ratio is from 1:1 to 1:100.

As may be understood from formulas (I) and (II), these compounds do not produce ammonium chloride upon their reaction, and the inventive method therefore does not suffer from the prior-art problem of ammonium chloride deposition.

The inert diluent gas that may be introduced into the CVD reaction chamber on an optional basis can be an inert gas such as nitrogen or a rare gas such as argon.

In order in accordance with the present invention to form a silicon oxynitride film on the substrate, at least one oxygen source gas is fed into the CVD reaction chamber along with the gaseous aminosilane, gaseous hydrazine compound, and (optional) diluent gas already described above with reference to the production of silicon nitride film. This oxygen source gas can be an oxygen-containing gas selected from the group consisting of oxygen (O₂), ozone (O₃), water vapor (H₂O), hydrogen peroxide (H₂O₂), nitric oxide (NO), nitrogen dioxide (NO₂), and nitrous oxide (N₂O).

The silicon oxynitride film can be formed on the substrate by reacting the gaseous aminosilane, gaseous hydrazine compound, and oxygen source gas using the same temperature and pressure conditions and gaseous aminosilane : gaseous hydrazine compound molar ratio already described above with reference to the production of silicon nitride film.

The oxygen source gas can be introduced into the CVD reaction chamber at a molar ratio with respect to the gaseous aminosilane of 1:1 to 1:100.

### EXAMPLES

This invention is described hereinbelow through examples, but this invention is not limited by these examples.

### Example 1

BTBAS gas, UDMH gas, and nitrogen (carrier gas) were introduced under the conditions given below into a reaction chamber holding a silicon substrate and a silicon nitride film was formed on the silicon substrate at temperatures of 525° C. to 620° C.

| | | |
|---|---|---|
| BTBAS gas flow rate: | 3.5 | sccm |
| UDMH gas flow rate: | 25 | sccm |
| nitrogen flow rate: | 35 | sccm |
| pressure in the reaction chamber: | 1.0 | torr |

The silicon nitride deposition (growth) rate was measured at 525° C., 550° C., 575° C., and 620° C. and its logarithmic value was plotted against the reciprocal of the reaction temperature (T in kelvin) times 1000. The results are reported in FIG. 1.

In addition, the Si/N atomic ratio of the silicon nitride grown at 620° C. was determined by Auger electron spectroscopy; the results are reported in Table 1. Table 1 also reports the silicon nitride growth rate at 620° C. and the reaction activation energy.

### Example 2

TIPAS gas, UDMH gas, and nitrogen (carrier gas) were introduced under the conditions given below into a reaction chamber holding a silicon substrate and a silicon nitride film was formed on the silicon substrate at temperatures of 550° C. to 620° C.

| | | |
|---|---|---|
| TIPAS gas flow rate: | 3.0 | sccm |
| UDMH gas flow rate: | 25 | sccm |
| nitrogen flow rate: | 30 | sccm |
| pressure in the reaction chamber: | 1.0 | torr |

The silicon nitride deposition (growth) rate was measured at 550° C., 575° C., 600° C., and 620° C. and its logarithmic value was plotted against the reciprocal of the reaction temperature (T in kelvin) times 1000. The results are reported in FIG. 2.

In addition, the Si/N atomic ratio of the silicon nitride grown at 620° C. was determined by Auger electron spectroscopy; the results are reported in Table 1. Table 1 also reports the silicon nitride growth rate at 620° C. and the reaction activation energy.

### Example 3

TEAS gas, UDMH gas, and nitrogen (carrier gas) were introduced under the conditions given below into a reaction chamber holding a silicon substrate and a silicon nitride film was formed on the silicon substrate at temperatures of 525° C. to 620° C.

| | | |
|---|---|---|
| TEAS gas flow rate: | 3.5 | sccm |
| UDMH gas flow rate: | 25 | sccm |
| nitrogen flow rate: | 35 | sccm |
| pressure in the reaction chamber: | 1.0 | torr |

The Si/N atomic ratio of the silicon nitride grown at 620° C. was determined by Auger electron spectroscopy; the results are reported in Table 1. Table 1 also reports the silicon nitride growth rate at 620° C. and the reaction activation energy.

### Comparative Example 1

Silicon nitride was grown on a silicon substrate as described in Example 1, but in this case using ammonia in place of the UDMH gas. The Si/N atomic ratio of the silicon nitride grown at 620° C. was determined by Auger electron spectroscopy; the results are reported in Table 1. Table 1 also reports the silicon nitride growth rate at 620° C. and the reaction activation energy.

### Comparative Example 2

Silicon nitride was grown on a silicon substrate as described in Example 2, but in this case using ammonia in place of the UDMH gas. The Si/N atomic ratio of the silicon nitride grown at 620° C. was determined by Auger electron spectroscopy; the results are reported in Table 1. Table 1 also reports the silicon nitride growth rate at 620° C. and the reaction activation energy.

### Comparative Example 3

Silicon nitride was grown on a silicon substrate as described in Example 3, but in this case using ammonia in place of the UDMH gas. The Si/N atomic ratio of the silicon nitride grown at 620° C. was determined by Auger electron spectroscopy; the results are reported in Table 1. Table 1 also reports the silicon nitride growth rate at 620° C. and the reaction activation energy.

TABLE 1

| | silicon nitride | reaction | |
|---|---|---|---|
| | growth | activation | Si/N atomic |
| | rate at 620° C. | energy | ratio in the |
| | angstroms/minute | kcal/mol | silicon nitride |
| Example 1 | 280 | 50 | 0.98 |
| Comparative Example 1 | 40 | 56 | 0.99 |
| Example 2 | 55 | 43 | 0.83 |
| Comparative Example 2 | 15 | 60 | 0.95 |
| Example 3 | 17 | 41 | 0.78 |
| Comparative Example 3 | 15 | 52 | 0.79 |

As the preceding examples make clear, this invention enables the relatively low temperature growth of high-quality silicon nitride at a relatively low activation energy.

### BRIEF DESCRIPTION OF THE DRAWINGS

FIG. 1 contains a graph that shows the relationship between the CVD reaction temperature and silicon nitride growth rate in Example 1;

FIG. 2 contains a graph that shows the relationship between the CVD reaction temperature and silicon nitride growth rate in Example 2.

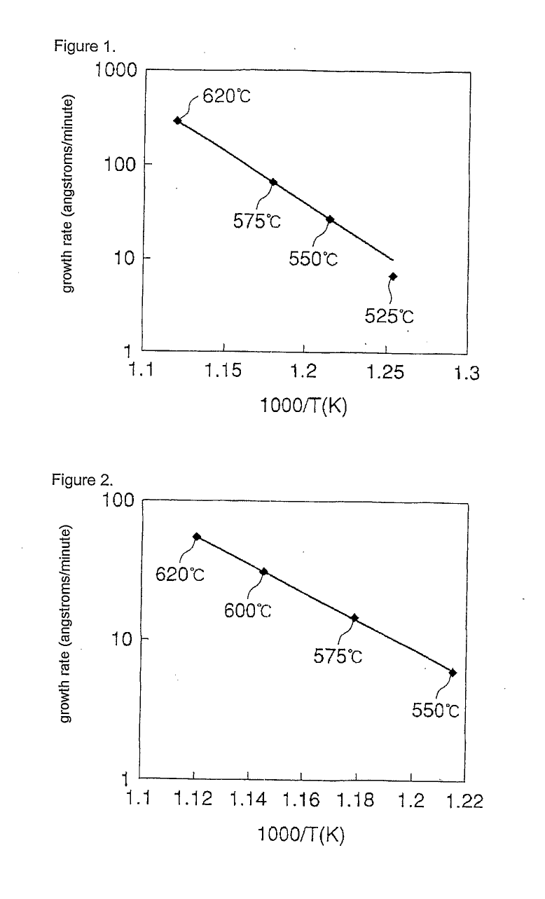

1-10. (canceled)

11. A method for producing silicon nitride film by chemical vapor deposition, characterized by
feeding gaseous aminosilane with formula (I)
(H)ₙ—Si—(N(R)₂)₄₋ₙ (I)
(each R is independently selected from the hydrogen atom, C₁₋₄ alkyl, and the trimethylsilyl group and n is an integer with a value of about 0-3,
wherein the groups R are not all simultaneously a hydrogen atom) and gaseous hydrazine compound with formula (II)
N₂(H)₄₋ₓ(R¹)ₓ (II)
(each R¹ is independently selected from methyl, ethyl, and phenyl and x is an integer with a value of about 0-4)
into a chemical vapor deposition reaction chamber that holds at least one substrate, and
forming silicon nitride film on said at least one substrate by reacting the two gases in the chemical vapor deposition reaction chamber.

12. The method of claim 11, wherein the reaction is run at temperatures of about 300° C. to about 650° C.

13. The method of claim 11, wherein the pressure in the reaction chamber is established at about 0.1-1000 torr.

14. The method of claim 11, wherein the aminosilane: hydrazine compound molar ratio is about 1:1 to about 1:100.

15. A method for producing silicon oxynitride film by chemical vapor deposition, characterized by
feeding gaseous aminosilane with formula (I)
(H)ₙ—Si—(N(R)₂)₄₋ₙ (I)
(each R is independently selected from the hydrogen atom, C₁₋₄ alkyl, and the trimethylsilyl group and n is an integer with a value of about 0-3,
wherein the groups R are not all simultaneously a hydrogen atom), gaseous hydrazine compound with formula (II)
N₂(H)₄₋ₓ(R¹)ₓ (II)
(each R¹ is independently selected from methyl, ethyl, and phenyl and x is an integer with a value of about 04), and oxygenated gas into a chemical vapor deposition reaction chamber that holds at least one substrate, and
forming silicon oxynitride film on said at least one substrate by reacting these gases in the chemical vapor deposition reaction chamber.

16. The method of claim 15 for producing silicon oxynitride film, wherein the oxygenated gas is at least one selection from the group consisting of O₂, O₃, H₂O, H₂O₂, NO, NO₂, and N₂O.

17. The method of claim 15, wherein the reaction is run at temperatures of about 300° C. to about 650° C.

18. The method of claim 15, wherein the pressure in the reaction chamber is established at about 0.1-1000 torr.

19. The method of claim 15, wherein the aminosilane:hydrazine compound molar ratio is about 1:1 to about 1:100.

20. The method of claim 15, wherein the aminosilane:oxygenated gas molar ratio is about 1:1 to about 1:100.
